(19) United States
(12) Patent Application Publication
(10) Pub. No.: US 2006/0066346 A1
(43) Pub. Date: Mar. 30, 2006

(54) Impedance compensation for I/O buffers

(76) Inventors: Eugene Soon Tat Lim, Penang (MY); Kok Leng Lim, Penang (MY); Yin Hao Liew, Penang (MY); Srinivasan Rajagopalan, Palo Alto, CA (US)

Correspondence Address: SCHWEGMAN, LUNDBERG, WOESSNER & KLUTH, 1600 TCF TOWER, 121 SOUTH EIGHT STREET, MINNEAPOLIS, MN, 55402, US

(21) Appl. No.: 10/953,143

(22) Filed: Sep. 28, 2004

(51) Int. Cl. H03K 19/003

(52) U.S. Cl. 326/30

(57) ABSTRACT

An apparatus comprising a voltage divider, a counter and a comparison circuit. The voltage divider is coupled to a first reference and includes a reference impedance and an adjustable impedance circuit coupled to the reference impedance circuit at a first node. The adjustable impedance circuit includes inputs to adjust the impedance according to a weighted coding pattern. The counter includes at least one input to cause the counter to count and change counter outputs in accordance with a weighted coding pattern that includes a pseudo-thermometer code. The counter outputs are coupled to the inputs of the adjustable impedance circuit. The comparison circuit is coupled to the first node and causes the counter to count in accordance with an outcome of a comparison between the first node and a second reference.

### BACKGROUND

Interface circuits are used to transmit and receive electrical signals between devices in electronic systems. These systems include digital systems where the signals communicated between the devices transition between high and low voltage levels. In some of these systems electrical signals need to be transmitted between integrated circuits (ICs). Interface circuits are used to minimize the effects of signal reflections on transmission lines interconnecting the integrated circuits.

Signal reflections occur from mismatches between signal source impedances and signal destination impedances. Because the signals transition between high and low voltage levels and because the transmission lines are lossy, the reflected signals eventually die out and a steady state is achieved on the signal transmission line. However, waiting for the signal to reach steady state results in delays in reading the signal on the transmission line. These delays eventually became unacceptable as switching speeds of integrated circuit continue increased.

To minimize reflections, designers of electrical systems try to match the source and destination as closely as possible. This matching is typically addressed in the design of input/output (I/O) buffer circuits in the integrated circuits. However, variances in impedances due to fabrication processes, voltages used, and temperatures to which the integrated circuits are exposed make this process difficult. The variances also make it difficult to create designs that are portable among applications.

### BRIEF DESCRIPTION OF THE DRAWINGS

FIG. 1 shows a block diagram of an embodiment of a circuit to tune an impedance.

FIG. 2 shows a block diagram of an embodiment of a circuit that tunes an impedance of a plurality of transistors according to a reference impedance.

FIG. 3 shows a block diagram of an embodiment of a system to improve the process of impedance matching of integrated circuits.

FIG. 4 is a block diagram of an embodiment of a method to improve the process of impedance matching of integrated circuits.

### DETAILED DESCRIPTION

In the following detailed description, reference is made to the accompanying drawings which form a part hereof, and in which is shown by way of illustration specific embodiments in which the invention may be practiced. It is to be understood that other embodiments may be used and structural and logical changes may be made without departing from the scope of the present invention.

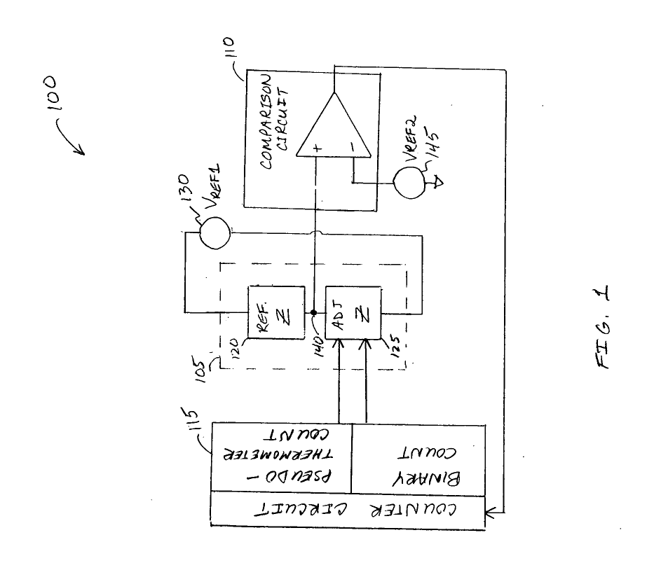

This document describes systems and methods to improve the process of impedance matching of integrated circuits. FIG. 1 shows a block diagram of an embodiment of a circuit 100 to tune an impedance of an integrated circuit (IC). Variances in impedances due to fabrication processes, voltages used, and changes in temperatures make it difficult to match impedances and ultimately minimize signal reflections between ICs. The variances in impedance also make it difficult to create designs that are portable among applications. For example, an IC interface may be exposed to different load impedances from one application to another. One approach to matching impedances is to add circuitry at the input/output (I/O) buffers on an integrated circuit to tune signal interface impedances to the application. The circuitry allows impedances to be adjusted as measurements of signal reflections are made. The I/O buffers contain registers to adjust the impedance. Writing a binary code into the registers causes a different impedance to be realized at the I/O Buffers.

However, it is difficult to know precisely when the reflection hits a receiver due to variances in the system such as transmission line length. This makes it difficult to know when to read the signal on the transmission line in order to adjust the impedance during an impedance tuning process. Taking a conservative approach that waits for a steady state in the transmission lines leads to dead time in the impedance switching. This lengthens the tuning process and adds cost to developing and implementing the design.

Additionally, adjusting an impedance during the tuning process can result in impedance glitches that add reflections to the system and compound the problem. For example, as the impedance is tuned by advancing a binary code in the registers, a code value change may result in rollover of several bits in the register, such as “0111” to “1000” for example. Due to the relative change in bit switching times, a rollover of several bits in the register will cause a glitch in the impedance of the I/O Buffers. A glitch that causes a full signal reflection on the transmission line causes errors in the impedance tuning process. Thus, it is important to minimize glitches while tuning the impedance.

The circuit 100 in FIG. 1 includes a voltage divider 105, a comparison circuit 110, and a counter 115. The voltage divider 105 includes a reference impedance 120 and an adjustable impedance circuit 125. In some embodiments, the reference impedance 120 includes a precision resistor. In some embodiments, the reference impedance 120 includes a circuit representing combinations of impedances. The adjustable impedance circuit 125 includes inputs to adjust the impedance according to a weighted code pattern that includes a thermometer code pattern. A thermometer code pattern is a binary pattern where the number of ones in the code corresponds to the decimal value. For example, “0111” represents decimal number three and adjusts the impedance of the circuit 125 three times as high as “0001.” In one embodiment, the weighted code pattern includes a binary code pattern. For example, a code input pattern of “0100,” or four, adjusts the impedance of the circuit 125 twice as high as when the code input pattern is “0010,” or two. Embodiments with other code weightings are within the scope of this document.

Outputs of counter 115 are coupled to inputs of the adjustable impedance circuit 125. The counter 115 counts according to a weighted code pattern that includes a pseudo-thermometer code. As the counter 115 counts, the counter outputs change according to the pattern. Because the outputs of the counter 115 are coupled to the inputs of the adjustable impedance circuit 125, the impedance changes according to the weighted code pattern as the outputs change.

The voltage divider divides a first reference 130 (V_{REF1}) to produce a voltage at a first node 140 that is coupled to an input of the comparison circuit 110. In some embodiments, the first reference 130 is the difference between a supply voltage VCC and ground. The other input of the comparison circuit 110 is coupled to a second voltage reference 145 (V_{REF2}). The output of the comparison circuit 110 is connected to an input of the counter 115. Based on the comparison of the inputs of the comparison circuit 110, a signal from the output of the comparison circuit 110 causes the counter 115 to count.

In one embodiment, when the voltage at the first node 140 is less than V_{REF2}, a signal is output to cause the counter 115 to decrement. The decrease in the count causes the adjustable impedance to increase which raises the voltage at the first node 140. When the voltage at the first node 140 is greater than V_{REF2}, a signal is output to cause the counter 115 to increment. The increase in the count causes the adjustable impedance to decrease which lowers the voltage at the first node 140. In an alternative embodiment, an increase in the count causes the impedance to increase and a decrease in the count causes the impedance to decrease. The comparison circuit 110 causes the output to change until the count reaches a steady state and an impedance value is obtained. In one embodiment, the steady state is reached when the output of the comparison circuit 110 oscillates or “dithers” between a signal to increment the count and a signal to decrement the count. For example, if a low or “0” output signal causes the counter 115 to increment, and a high or “1” causes the counter 115 to decrement, a steady state is reached when the output signal changes as 010101, . . . and so on. When a steady state is reached, the voltage at the first node 140 matches the voltage of V_{REF2}. In one embodiment, V_{REF2} is chosen to be one-half the value of V_{REF1} and the adjustable impedance matches the reference impedance when the voltage at the first node 140 matches the voltage of V_{REF2}. Different values of impedance in relation to the reference voltage can be found by changing the value of V_{REF2} in relation to V_{REF1}.

Because the counter counts according to a pseudo-thermometer code, the counter does not roll over a large number of count bits that would normally cause a glitch in the impedance. Table 1 shows an embodiment of a pseudo-thermometer code.

TABLE 1
Pseudo-thermometer coding

| RComp | 2x | 2x | 2x | 1x | 1x | 1x | 1x |
|---|---|---|---|---|---|---|---|
| setting | bit 6 | bit 5 | bit 4 | bit 3 | bit 2 | bit 1 | bit 0 |
| 0 | 0 | 0 | 0 | 0 | 0 | 0 | 0 |
| 1 | 0 | 0 | 0 | 0 | 0 | 0 | 1 |
| 2 | 0 | 0 | 0 | 0 | 0 | 1 | 1 |
| 3 | 0 | 0 | 0 | 0 | 1 | 1 | 1 |
| 4 | 0 | 0 | 0 | 1 | 1 | 1 | 1 |
| 5 | 0 | 0 | 1 | 1 | 1 | 1 | 0 |
| 6 | 0 | 0 | 1 | 1 | 1 | 1 | 1 |
| 7 | 0 | 1 | 1 | 1 | 1 | 1 | 0 |
| 8 | 0 | 1 | 1 | 1 | 1 | 1 | 1 |
| 9 | 1 | 1 | 1 | 1 | 1 | 1 | 0 |
| 10 | 1 | 1 | 1 | 1 | 1 | 1 | 1 |

In the embodiment, seven bits are used to encode eleven states. The outputs of the counter 115 are connected to the adjustable impedance circuit 125 according to the code weight. Thus a code weight output of 1× is connected to an input such that an active level on that output changes the adjustable impedance by 1× of a unit impedance. Similarly, a change in a 2× code weight changes the adjustable impedance by 2× of the unit impedance. The code is a pseudo-thermometer code because some of the code bits have a weight of 2× rather than all weights of 1× as in a pure thermometer code. Note that at most two bits change levels between any two successive states and the change in weight between any two states is 1×.

In some embodiments, the counter 115 includes a pseudo-thermometer code combined with a binary code. Table 2 shows a binary coding scheme using five bits. The Tables show that a combination of the binary coding scheme and pseudo-thermometer coding scheme produces forty-one states from twelve bits. In some of the embodiments, the counter 115 includes logic to enable only the binary code portion to count until a first steady state is reached and to enable only the pseudo-thermometer code portion to count until a second steady state is reached. A steady state is reached when the output of the comparison circuit 110 dithers between a signal to increment the count and decrement the count.

TABLE 2
Binary coding

| | 16x | 8x | 4x | 2x | 1x |
|---|---|---|---|---|---|
| RComp setting | bit 11 | bit 10 | bit 9 | bit 8 | bit 7 |
| 0 | 0 | 0 | 0 | 0 | 0 |
| 1 | 0 | 0 | 0 | 0 | 1 |
| 2 | 0 | 0 | 0 | 1 | 0 |
| 3 | 0 | 0 | 0 | 1 | 1 |
| 4 | 0 | 0 | 1 | 0 | 0 |
| 5 | 0 | 0 | 1 | 0 | 1 |
| 6 | 0 | 0 | 1 | 1 | 0 |
| 7 | 0 | 0 | 1 | 1 | 1 |
| 8 | 0 | 1 | 0 | 0 | 0 |
| 9 | 0 | 1 | 0 | 0 | 1 |
| 10 | 0 | 1 | 0 | 1 | 0 |
| 11 | 0 | 1 | 0 | 1 | 1 |
| 12 | 0 | 1 | 1 | 0 | 0 |
| 13 | 0 | 1 | 1 | 0 | 1 |
| 14 | 0 | 1 | 1 | 1 | 0 |
| 15 | 0 | 1 | 1 | 1 | 1 |
| 16 | 1 | 0 | 0 | 0 | 0 |
| 17 | 1 | 0 | 0 | 0 | 1 |
| 18 | 1 | 0 | 0 | 1 | 0 |
| 19 | 1 | 0 | 0 | 1 | 1 |
| 20 | 1 | 0 | 1 | 0 | 0 |
| 21 | 1 | 0 | 1 | 0 | 1 |
| 22 | 1 | 0 | 1 | 1 | 0 |
| 23 | 1 | 0 | 1 | 1 | 1 |
| 24 | 1 | 1 | 0 | 0 | 0 |
| 25 | 1 | 1 | 0 | 0 | 1 |
| 26 | 1 | 1 | 0 | 1 | 0 |
| 27 | 1 | 1 | 0 | 1 | 1 |
| 28 | 1 | 1 | 1 | 0 | 0 |
| 29 | 1 | 1 | 1 | 0 | 1 |
| 30 | 1 | 1 | 1 | 1 | 0 |
| 31 | 1 | 1 | 1 | 1 | 1 |

In the embodiments, only the binary portion is first allowed to count while holding the pseudo-thermometer portion frozen until dithering occurs. Then, only the pseudo-thermometer portion is allowed to count while holding the binary portion frozen until dithering occurs. Thus, a coarse adjustment is provided by the binary code and a fine adjustment is provided by the pseudo-thermometer code.

In some embodiments the circuit 100 is included in an integrated circuit die and the reference impedance is external to the integrated circuit die. In one embodiment, the reference impedance is a precision resistor coupled to a die pad. In this way, the impedance on the integrated circuit can be tuned to an impedance external to the integrated circuit, such as an external impedance due to a printed circuit board, a coaxial connection, or combinations of external impedances.

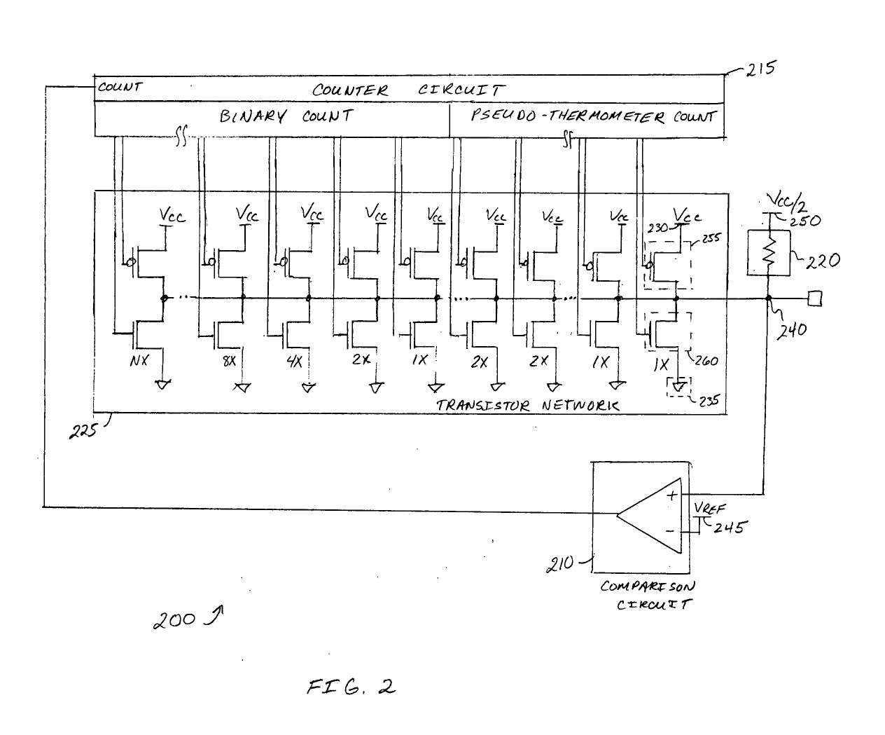

FIG. 2 shows a block diagram of an embodiment of a circuit 200 that tunes an impedance of a plurality of transistors according to a reference impedance. The circuit 200 includes a counter 215 and a comparison circuit 210. At least a portion of the counter 215 counts according to a pseudo-thermometer code. A voltage divider includes a reference resistance 220 coupled to an adjustable impedance circuit 225 at an output node 240. The adjustable impedance circuit 225 includes a plurality of transistors where the transistor inputs are coupled to the outputs of the counter 215. An active state at the input applies the transistor resistance to the output node 240 to adjust the division ratio of the voltage divider. The resistance is adjusted by changing the number of transistors that are active. Because switch resistance of a transistor varies in proportion to its width-to-length ratio, increasing the number of transistors on the node 240 decreases the resistance.

One or a combination of the transistor inputs are coupled to outputs of the counter 215 so that the transistors realize weighted multiples of a unit impedance value that correspond to the weights of the outputs. The multiples can be formed from connecting together multiples of a unit-sized transistor or creating different transistors sizes that have width to length ratios that are multiples of a unit-sized width to length ratio. The adjustable impedance circuit 225 includes transistor resistances of 1× and 2× attached to the portion of the counter 215 that counts according to a pseudo-thermometer code, and transistor impedances of 1× through NX attached to the portion of the counter 215 that counts according to a binary code; N being a binary integer.

In the embodiment shown, the adjustable impedance circuit 225 includes a network of PMOS transistors 255 and a network of NMOS transistors 260. The circuit also includes enable/disable logic to disable the PMOS network, the NMOS network, or both. By disabling one or the other network, the circuit 200 is able to tune the networks separately. When the PMOS network is being tuned, the voltage difference between V_{CC} and V_{CC}/2 is divided between the PMOS network and the reference resistance circuit 220 to produce a voltage at a first node 240 that is coupled to one input of the comparison circuit 210. The other input of the comparison circuit 210 is coupled to a first reference 245 (V_{REF}). When the count increases, more transistor inputs become active and the PMOS impedance decreases. When the NMOS network is being tuned, the voltage difference between V_{CC}/2 and ground is divided between the NMOS network and the reference resistance circuit 220 to produce a voltage at the output node 240. When the count increases, the NMOS impedance decreases.

In another embodiment, a second reference is coupled to the comparison circuit 210. A comparison is made between the first reference 245 and the output node 240 to obtain a count, or impedance code value, for the PMOS network, and a comparison is made between the second reference and the output node 240 to obtain an impedance code value for the NMOS network. Only one network is active at a time when tuning the impedance. Enabling both networks causes indeterminate results.

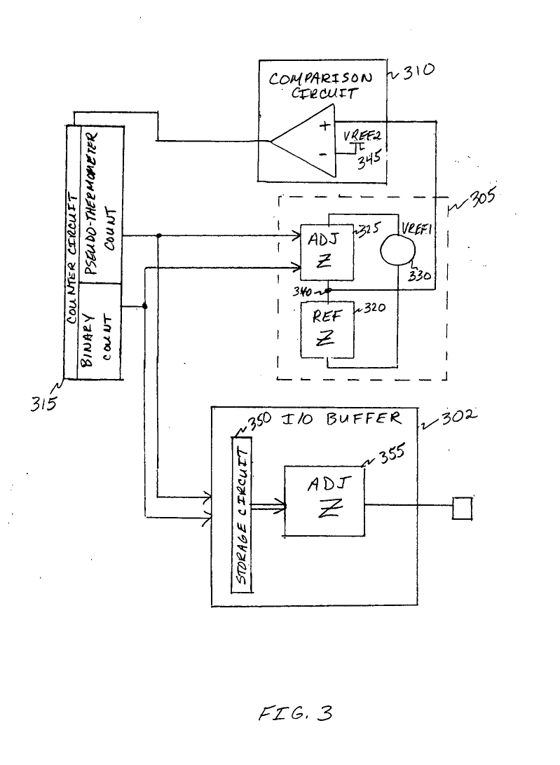

FIG. 3 shows a block diagram of an embodiment of a system 300 to improve the process of impedance matching of integrated circuits. The system 300 comprises an impedance measuring circuit and at least one I/O buffer circuit 302.

The impedance measurement circuit includes a voltage divider 305, a comparison circuit 310, and a counter 315. The voltage divider 305 divides a first reference 330 (V_{REF1}) to produce a voltage on an output node 340. The voltage divider includes a reference impedance circuit 320 coupled to an adjustable impedance circuit 325 at the output node 340. The adjustable impedance circuit 325 includes inputs to adjust the impedance according to a weighted coding scheme. Outputs of the counter 315 are coupled to inputs of the adjustable impedance circuit 325. The counter 315 counts according to a weighted code pattern that includes a pseudo-thermometer code. Because the outputs of the counter 315 are coupled to the inputs of the adjustable impedance circuit 325, the adjustable impedance changes according to the weighted code pattern as the counter 315 counts.

The voltage divider 305 produces a voltage at the output node 340 that is coupled to an input of the comparison circuit 310. The other input of the comparison circuit 310 is coupled to a second voltage reference 345 (V_{REF2}). The output of the comparison circuit 310 is connected to an input of the counter 315. Based on the comparison of the inputs of the comparison circuit 310, a signal from the output of the comparison circuit 310 causes the counter 315 to count.

In one embodiment, when the voltage at the output node 340 is less than V_{REF2}, a signal is output from the comparison circuit 310 to cause the counter 315 to increment. The increase in the count causes the adjustable impedance to decrease which raises the voltage at the output node 340. When the voltage at the output node 340 is greater than V_{REF2}, a signal is output to cause the counter 315 to decrement. The decrease in the count causes the adjustable impedance to increase which lowers the voltage at the output node 340. In another embodiment, the positions of the reference impedance circuit 325 and the adjustable impedance circuit 320 are interchanged and the impedance is adjusted similar to the embodiment in FIG. 1. The comparison circuit 310 causes the counter outputs to change until the count reaches a steady state and an impedance value is obtained. When the count reaches a steady state, the count provides a code value corresponding to the obtained impedance value. If V_{REF2} is equal to one-half the value of V_{REF1}, the count reaches a steady state when the adjustable impedance matches the reference impedance. In this case, the adjustable impedance is tuned to the reference impedance. Different impedance values can be obtained from the adjustable impedance circuit 325 by changing V_{REF2}. Because at least a portion of the counter 315 counts according to a pseudo-thermometer code, glitches are minimized in the system when the impedance changes.

The I/O buffer circuit 302 includes a storage circuit 350 coupled to an adjustable impedance circuit 355. The storage circuit 350 stores the impedance code value obtained when the counter 315 reaches a steady state. The I/O buffer adjustable impedance circuit 355 includes inputs to adjust the impedance according to a weighted coding scheme. Thus, the value stored in the storage circuit 350 sets the impedance of the adjustable impedance circuit 355 according to the value of the impedance code.

In some embodiments, the I/O buffer adjustable impedance circuit 355 is the same as the adjustable impedance circuit 325 of the impedance measurement circuit. In some of the embodiments, storing the impedance code value in the storage circuit 350 sets the I/O buffer 302 impedance equal to the measured steady state impedance value. If the adjustable impedance was tuned to the reference impedance, the I/O buffer impedance is set equal to the reference impedance. If the reference impedance is representative of an impedance of a signal source or destination, the I/O buffer circuit 302 impedance is matched to the impedance and signal reflections are minimized.

In other embodiments, the system further includes an update circuit coupled between the counter 315 and the storage circuit 350. The update circuit includes logic to scale the impedance code value by a multiple, to add an offset to the impedance code value, or both to obtain an updated impedance code value. The term “logic” includes any logic circuits used to implement the scaling or multiplying and providing an offset to the impedance code value. In some of these embodiments, the system 300 includes groups of at least one I/O buffer circuit 302. The buffers can be grouped according to values of external impedance at the buffer interfaces, or by function of the I/O signals. Each group of I/O buffers includes a storage circuit 350. Either the impedance code value or an updated impedance code value can be stored in the storage circuits 350 to set the impedance of each group of buffers. In one embodiment, one I/O buffer circuit 302 is dedicated for use as the adjustable impedance circuit 325 for impedance tuning.

Once an impedance code value is obtained for one group of I/O buffers, previous circuit simulation has shown what impedance can be expected for the other groups of buffers. The update circuit then provides an updated impedance code value appropriate for the other groups of buffers. For example, assume the I/O buffer circuits 302 are on an integrated circuit (IC) that interfaces to other ICs. It is known that all clock I/O buffers drive two ICs and all data I/O buffers drive one IC. Also assume that the reference impedance circuit 320 represents the impedance seen at the data I/O buffers, and simulation has shown that the impedance seen at the clock I/O buffers is twice that of the data I/O buffers. Once the impedance code value for the data I/O buffers is obtained from the impedance measurement circuit, the update circuit scales the impedance code value by two before the impedance code value is stored in the storage circuit 350 for the clock I/O buffers. In some embodiments, the system further includes a memory circuit, and the value used by the update circuit to scale the impedance code value, to offset the impedance code value, or both is stored in a look-up table in the memory circuit. In some of the embodiments, the memory circuit includes a static random access memory (SRAM).

In some embodiments, the adjustable impedance circuits 325, 355 include a plurality of transistors. For the adjustable impedance circuit 325 of the impedance measurement circuit, the transistors are connectable to apply multiples of a unit impedance value to the output node 340. The inputs of the transistors are coupled to the outputs of the counter 315. An active state from a counter output provided at the input of a transistor applies the transistor impedance to the first node 340 to adjust the division ratio of the voltage divider 305. In some embodiments, the plurality of transistors includes a PMOS transistor network and an NMOS transistor network. An enable/disable input to the networks causes only the PMOS network or only the NMOS network to be active at the first node 340. By disabling one or the other network, the system 300 is able to tune the networks separately to obtain a PMOS impedance code value and an NMOS impedance code value.

For the I/O buffer adjustable impedance circuit 355, the transistors are included in the interface drive circuit of the buffers. In some embodiments, the PMOS and NMOS transistors are the I/O buffer pull-up and pull-down drivers respectively. The impedance code value or values written into the storage circuit 350 determine how many transistors are added to the pull-up and the pull-down circuits.

According to some embodiments, the I/O buffer circuit 302 further includes a slew rate control circuit. The slew rate is determined from a slew rate value provided to the slew rate control circuit. Previous circuit simulation is used to determine what slew rate value corresponds to an impedance code value. In some the embodiments, the system 300 includes a memory circuit for storing a slew rate look-up table and the values for the slew rates corresponding to the impedance code values are stored in the look-up table.

In some embodiments, the I/O buffer circuit 302 is included in an integrated circuit die and the reference impedance circuit 320 is external to the integrated circuit die. In some of the embodiments, the integrated circuit die is to be mounted on a printed circuit board and the reference impedance corresponds to a printed circuit board (PCB) impedance. In other embodiments, the reference impedance is a combination of impedances. For example the reference impedance may represent a lumped impedance of a PCB impedance with a coaxial transmission line impedance. In some embodiments, the integrated circuit die includes a processor. In some embodiments, the integrated circuit die is included in a network controller.

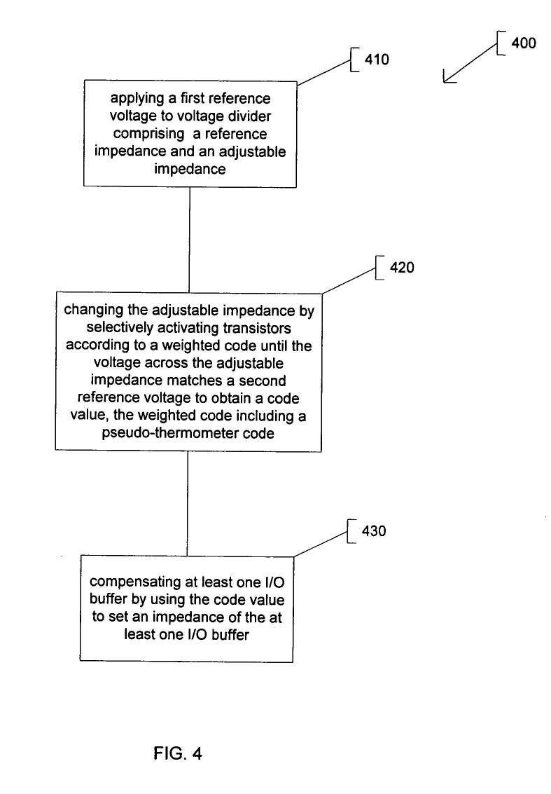

FIG. 4 is a block diagram of an embodiment of a method 400 to improve the process of impedance matching of integrated circuits. At 410, a first reference voltage is applied to a voltage divider comprising a reference impedance and an adjustable impedance. At 420, the adjustable impedance is changed by selectively activating transistors according to a weighted code until the voltage across the adjustable impedance matches a second reference voltage. When the voltages match, a weighted code value is obtained. In some embodiments, the voltages match when the adjustable impedance matches the reference impedance. The weighted code includes a pseudo-thermometer code in order to minimize glitches in impedance values when the impedance is adjusted. At 430, at least one I/O buffer is compensated by using the weighted code value to set an impedance of the at least one I/O buffer.

In some embodiments, the transistors include a network of PMOS transistors and a network of NMOS transistors. In the embodiments, dividing the first reference voltage includes first dividing the reference voltage between the reference impedance and a PMOS transistor network. The adjustable impedance is changed to obtain a PMOS impedance code value for the PMOS transistor network. The first reference voltage is then divided between the reference impedance circuit and an NMOS transistor network. The adjustable impedance is changed to obtain an NMOS impedance code value for the NMOS transistor network. Compensating at least one I/O buffer includes using the impedance code values to compensate pull-up and pull-down circuits for the at least one I/O buffer. The impedances of the pull-up and pull-down circuit are set relative to the reference impedance. In some of the embodiments, this includes scaling the impedance code value, adding an offset to the code value, or both to set the relative impedance.

In some embodiments, changing the adjustable impedance includes selectively activating transistors according to a coarse impedance adjustment weighted according to a binary code and a fine impedance adjustment weighted according to a pseudo-thermometer code. In some of the embodiments, changing the adjustable impedance value includes changing only the binary code portion until a first steady state is reached and changing only the pseudo-thermometer code portion until a second steady state is reached. A steady state is reached when the voltage across the adjustable impedance is sufficiently close to the second reference voltage so that no meaningful changes occur in the weighted code as the impedance is adjusted.

In some method embodiments, compensating the at least one I/O buffer includes compensating a plurality of I/O buffers using the impedance code value to set the impedance of the I/O buffers. In some of the embodiments, compensating includes compensating groups of at least one I/O buffer by using the code value to obtain a group code value, if necessary, by scaling the code value, or by adding an offset to the code value, or both. Setting an impedance of a group of I/O buffers includes using either the impedance code value or the group impedance code value.

In some embodiments, the method further includes setting a slew rate of the at least one I/O buffer using the impedance code value. In some of the embodiments, setting a slew rate includes looking up a slew rate value in a look up table using the code value.

The accompanying drawings that form a part hereof, show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein, individually, collectively, or both by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own.

What is claimed is:

1. An apparatus comprising:
a voltage divider coupled to a first reference, the divider comprising a reference impedance and an adjustable impedance circuit, the impedance of the adjustable circuit changeable according to a weighted coding pattern;
a counter having outputs coupled to inputs of the adjustable impedance circuit, the counter outputs changing in accordance with a weighted coding pattern that includes a pseudo-thermometer code; and
a comparison circuit coupled to cause the counter to count in accordance with an outcome of a comparison between a divider output and a second reference.

2. The apparatus of claim 1, wherein the comparison circuit output is coupled to the counter to cause the counter to increment or decrement in accordance with the comparison and the adjustable impedance to change according to the weighted code pattern until the counter reaches a steady state and an impedance value is obtained.

3. The apparatus of claim 2, wherein the counter includes a portion that counts according to a binary code and a portion that counts according to a pseudo-thermometer code, and wherein the counter includes logic to enable only the binary code portion to count until a first steady state is reached and to enable only the pseudo-thermometer code portion to count until a second steady state is reached.

4. The apparatus of claim 1, wherein the voltage divider output is coupled to a first node and the adjustable impedance circuit includes a plurality of transistors connectable to apply multiples of a unit impedance value to the first node, each transistor having an input wherein an active state at the input applies the transistor impedance to the first node to adjust the division ratio of the voltage divider, and wherein the counter weighted code outputs are coupled to provide active states to the inputs of one or a combination of the transistors to apply weighted multiples of the unit impedance value to the first node.

5. The apparatus of claim 4, wherein the transistor network includes a PMOS transistor network, an NMOS transistor network, and at least one enable/disable input to disable the PMOS network, the NMOS network, or both.

6. The apparatus of claim 5, wherein the comparison circuit is further coupled to a third reference voltage, wherein the counter changes count in accordance with an outcome of a comparison between the first node and the second reference voltage to obtain a PMOS impedance code value, and wherein the counter changes count in accordance with an outcome of a comparison between the first node and the third reference voltage to obtain an NMOS impedance code value.

7. The apparatus of claim 1, wherein the apparatus is included in an integrated circuit die and the reference impedance is external to the integrated circuit die.

8. An apparatus comprising,
an impedance measurement circuit including:
a voltage divider coupled to a first reference, the voltage divider including:
a reference impedance circuit; and
an adjustable impedance circuit coupled to the reference impedance circuit at a first node, the adjustable impedance circuit having inputs to adjust the impedance according to a weighted coding scheme;
a counter including at least one input to cause the counter to count in accordance with the weighted coding scheme and including weighted code outputs coupled to the inputs of the adjustable impedance circuit, wherein at least a portion of the weighted coding scheme includes a pseudo-thermometer code; and
a comparison circuit coupled to the first node to cause the counter to count in accordance with a comparison between the first node and a second reference to obtain an impedance code value when the counter reaches a steady state; and
at least one I/O buffer circuit including:
a storage circuit to store the impedance code value; and
an adjustable impedance circuit coupled to the storage circuit, wherein a stored impedance code value determines an I/O buffer impedance value.

9. The apparatus of claim 8, wherein the apparatus further includes an update circuit coupled between the counter and the storage circuit, wherein the update circuit includes logic to scale the impedance code value by a multiple, add an offset to the impedance code value, or both to obtain an updated impedance code value.

10. The apparatus of claim 8, wherein the at least one I/O buffers includes groups of at least one I/O buffer, each group including a storage circuit, and wherein the update circuit provides the impedance code value or the updated impedance code value to the group storage circuit.

11. The apparatus of claim 8, wherein the at least one I/O buffer includes a slew rate control circuit including a slew rate storage circuit, and wherein a slew rate value corresponding to the impedance code value is provided to the slew rate storage circuit.

12. The apparatus of claim 11, wherein the apparatus further includes a memory circuit for storing a slew rate look-up table, wherein a slew rate value from the look-up table corresponding to the impedance code value is provided to the slew rate storage circuit.

13. The apparatus of claim 8, wherein the adjustable impedance circuit includes a plurality of transistors connectable to apply multiples of a unit impedance value to the first node, each transistor having an input wherein an active state at the input applies the transistor impedance to the first node to adjust the division ratio of the voltage divider, and wherein the counter weighted code outputs are coupled to provide active states to the inputs of one or a combination of the transistors to apply weighted multiples of the unit impedance value to the first node.

14. The apparatus of claim 13, wherein the plurality of transistors includes a PMOS transistor network, an NMOS transistor network, and an enable/disable input, the enable/disable input to cause only the PMOS network or only the NMOS network to be active at the first node, wherein the counter obtains a PMOS impedance code value and an NMOS impedance code value in accordance with an active transistor network and wherein the storage circuit stores the PMOS impedance code value and the NMOS impedance code value.

15. The apparatus of claim 8, wherein the at least one I/O buffer is included in an integrated circuit die.

16. The apparatus of claim 15, wherein the reference impedance is external to the integrated circuit die.

17. The apparatus of claim 16, wherein the integrated circuit die is to be mounted on a printed circuit board and the reference impedance corresponds to a printed circuit board impedance.

18. A system comprising,
a memory circuit, the memory circuit including a static random access memory (SRAM); and a microprocessor including:
an impedance measurement circuit including:
a voltage divider coupled to a first reference, the divider comprising a reference impedance and an adjustable impedance circuit, the impedance of the adjustable circuit changeable according to a weighted coding pattern;
a counter having outputs coupled to inputs of the adjustable impedance circuit, the counter outputs changing in accordance with a weighted coding pattern that includes a pseudo-thermometer code; and
a comparison circuit coupled to cause the counter to count in accordance with an outcome of a comparison between a divider output and a second reference to obtain an impedance code value; and
at least one I/O buffer circuit including a storage circuit coupled to an adjustable impedance circuit, wherein an impedance code value stored in the storage circuit determines an I/O buffer impedance value.

19. The system of claim 18, wherein the system is included in a network controller.

20. The system of claim 18, wherein the system is included in an integrated circuit and the reference impedance circuit is external to the integrated circuit.

21. A method comprising:
applying a first reference voltage to a voltage divider comprising a reference impedance and an adjustable impedance;
changing the adjustable impedance by selectively activating transistors according to a weighted code until the voltage across the adjustable impedance matches a second reference voltage to obtain a code value, the weighted code including a pseudo-thermometer code; and
compensating at least one I/O buffer by using the code value to set an impedance of the at least one I/O buffer.

22. The method of claim 21, wherein dividing the first reference voltage between the reference impedance and the adjustable impedance includes dividing the first reference voltage between the reference impedance and a PMOS transistor network, and dividing the first reference voltage between the reference impedance circuit and an NMOS transistor network, and wherein changing the adjustable impedance to obtain a code value includes changing the adjustable impedance to obtain a PMOS code value for the PMOS transistor network and to obtain an NMOS code value for the NMOS transistor network.

23. The method of claim 21, wherein changing the adjustable impedance value by selectively activating transistors according to a weighted code includes providing a coarse impedance adjustment weighted according to a binary code and a fine impedance adjustment weighted according to a pseudo-thermometer code.

24. The method of claim 23, wherein changing the adjustable impedance value by selectively activating transistors according to a weighted code includes changing only the binary code until a first steady state is reached and changing only the pseudo-thermometer code until a second steady state is reached.

25. The method of claim 21, wherein changing the adjustable impedance value by selectively activating transistors until the voltage across the adjustable impedance matches a second reference voltage includes changing the adjustable impedance value until the voltage across the adjustable impedance matches a second reference voltage and the adjustable impedance matches the reference impedance.

26. The method of claim 21, wherein changing the adjustable impedance value by selectively activating transistors to obtain a code value further includes scaling the code value, adding an offset to the code value, or both.

27. The method of claim 21, wherein compensating the at least one I/O buffer includes compensating a plurality of I/O buffers using the code value to set an impedance of the plurality of I/O buffers.

28. The method of claim 21, wherein compensating the at least one I/O buffer by using the code value to set an impedance includes compensating groups of at least one I/O buffer by using the code value to obtain a group code value if necessary by scaling the code value, or adding an offset to the code value, or both and setting an impedance of a group of I/O buffers using either the code value or the group code value.

29. The method of claim 21, wherein the method further includes setting a slew rate of the at least one I/O buffer using the code value.

30. The method of claim 29, wherein setting a slew rate includes looking up a slew rate value in a look up table using the code value.
